(19) United States
(12) Patent Application Publication
(10) Pub. No.: US 2016/0262257 A1
(43) Pub. Date: Sep. 8, 2016

(54) Electronic Circuit Unit

(71) Applicant: Hitachi Automotive Systems, Ltd., Hitachinaka-shi (JP)

(72) Inventors: Hirofumi WATANABE, Isesaki-shi (JP); Mototaka TAKAHASHI, Ota-shi (JP); Kazuhiko NAKANO, Isesaki-shi (JP)

(21) Appl. No.: 15/061,117

(22) Filed: Mar. 4, 2016

(30) Foreign Application Priority Data
Mar. 6, 2015 (JP) 2015-044131

(51) Int. Cl. H05K 1/02; B60T 13/74

(52) U.S. Cl. CPC H05K 1/0209; B60T 13/745

(57) ABSTRACT

To increase vibration resistance of a connection terminal, a tip of which is soldered to a circuit board. In a controller, the circuit board is accommodated in a controller housing made of metal, and the tip of the connection terminal that extends from an actuator housing through an opening is fixed to the circuit board. Semiconductor switching elements and electrolytic capacitors as heat generating components are collectively arranged in an area of the circuit board adjacent to the connection terminal, and the circuit board is adhered and fixed to a top surface of a heat mass via a thermal conductive adhesive. At the same time as that heat dissipation is improved by the thermal conductive adhesive, a load caused by vibration is reduced because the circuit board is fixed at a position near the connection terminal to the controller housing.

### BACKGROUND OF THE INVENTION

1. Field of the Invention

The invention relates to an electronic circuit unit used for an electric brake device of an automobile, for example, and the like.

2. Description of Related Art

For example, an electric brake device for which an electric motor is used instead of a general negative-pressure type booster mechanism has been suggested as a brake device of an automobile. In Patent Reference 1, a configuration that the electric motor for constituting the booster mechanism and a controller for controlling the electric motor are integrated with a master cylinder is disclosed.

Patent Reference 1: JP-A-2010-93986

The electric brake device in which the electric motor, the controller, and the master cylinder are integrated as described above is supported in a so-called cantilevered manner by a dashboard of a vehicle in which a brake pedal is arranged. Accordingly, vibration caused by travel vibration and the like and received by the controller is relatively large. Thus, a circuit board of the controller tends to be vibrated in a housing, and there is still room for improvement in terms of vibration resistance of a connection terminal for connecting the electric motor and the circuit board, for example.

### SUMMARY OF THE INVENTION

The invention provides an electronic circuit unit that includes: a controller housing made of metal; a circuit board that has heat generating components mounted thereon and is accommodated in this controller housing; and a connection terminal that extends from outside of the controller housing and penetrates the controller housing, a tip of the connection terminal being connected to the circuit board, in which the plural heat generating components are collectively arranged in an area adjacent to the connection terminal, and in which the area of the circuit board is joined to a bottom surface of the controller housing via a thermal conductive adhesive.

In such a configuration, heat of the heat generating components is transferred to the controller housing that is made of metal, and favorable heat dissipation is realized. At the same time as this, the area in which the plural heat generating components are collectively arranged is fixed to the controller housing via the thermal conductive adhesive. Thus, vibration of the circuit board, particularly in the area adjacent to the connection terminal is inhibited. In this way, a load acting on the connection terminal that extends from the outside and is connected to the circuit board is reduced.

According to the invention, the circuit board is fixed to the controller housing at the position near the connection terminal by using the thermal conductive adhesive that dissipates the heat from the heat generating components to the controller housing, and vibration resistance of the connection terminal is improved.

### BRIEF DESCRIPTION OF THE DRAWINGS

FIG. 1 is a front view of an electric brake device that includes an electronic circuit unit according to the invention;

FIG. 2 is a side view of the same electric brake device;

FIG. 3 is an exploded perspective view of a main section of this electric brake device;

FIG. 4 is a plan view that depicts one embodiment of the electronic circuit unit according to the invention in a state where a cover is removed;

FIG. 5 is a plan view that depicts a circuit board as a single unit;

FIG. 6 is a cross-sectional view taken along lines 6-6 in FIG. 4;

FIG. 7 is a cross-sectional view in which a main section of FIG. 6 is enlarged;

FIG. 8 is an explanatory view in which a cross section of a portion B in FIG. 5 is enlarged;

FIG. 9 is a similar explanatory view to FIG. 8 that depicts a state where the circuit board is combined with a controller housing;

FIG. 10 is a plan view of a main section that depicts a second embodiment; and

FIG. 11 is an enlarged cross-sectional view of a main section taken along lines 11-11 in FIG. 10.

### DESCRIPTION OF THE PREFERRED EMBODIMENTS

A detailed description will hereinafter be made on embodiments of the invention on the basis of the drawings.

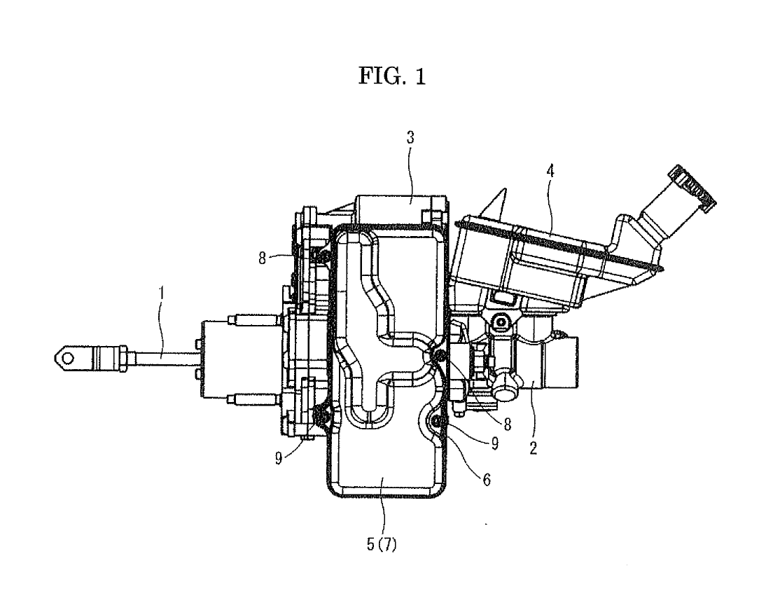

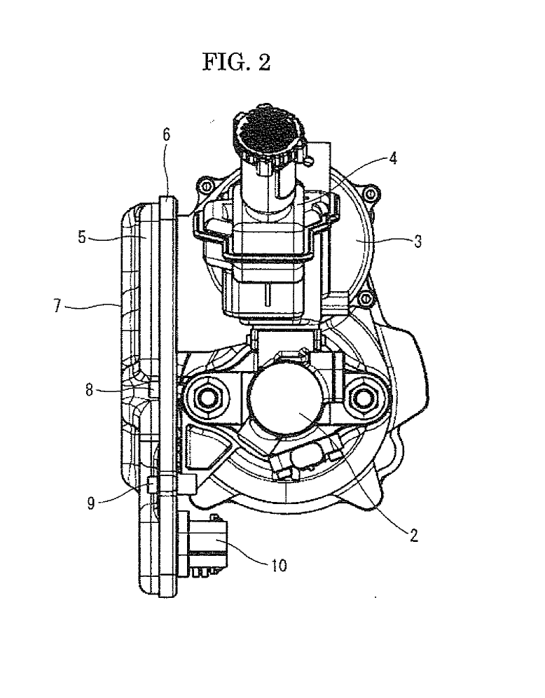

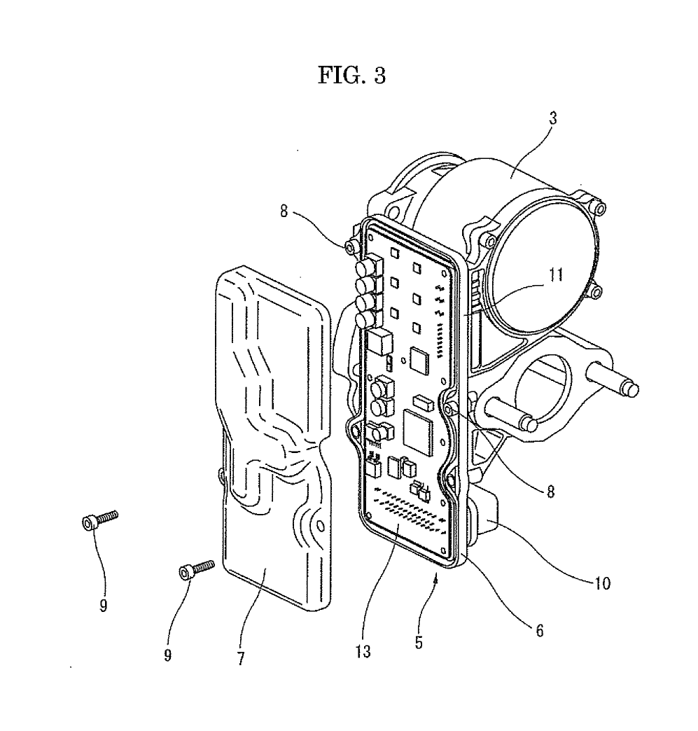

FIG. 1 and FIG. 2 are respectively a front view and a side view, each of which depicts an overall configuration of an electric brake device including an electronic circuit unit according to the invention. This electric brake device includes: an input rod 1 to which a brake pedal, which is not depicted, is coupled; a master cylinder 2 for supplying brake hydraulic pressure to a wheel cylinder of each wheel via a hydraulic circuit mechanism, which is not depicted; an actuator housing 3 for accommodating an electric motor that constitutes a booster mechanism and a ball screw mechanism (none of them is depicted); a reservoir tank 4; and a controller 5 for executing drive control of the electric motor, and these are configured as an integral unit. The controller 5 includes, as a casing: a controller housing 6 that has a rectangular shallow dish shape; and a cover 7 that also has the rectangular shallow dish shape and covers an opening surface of this controller housing 6. As depicted in FIG. 3, the controller housing 6 is attached to the actuator housing 3 by two screws 8, and the cover 7 is attached to the controller housing 6 by two other screws 9. A lower portion of the controller housing 6 is projected downward from the actuator housing 3, and a connector 10 that is made of a synthetic resin is attached to a back surface side of this projected portion. Note that FIG. 3 depicts a state where the input rod 1 and the master cylinder 2 are removed from the actuator housing 3.

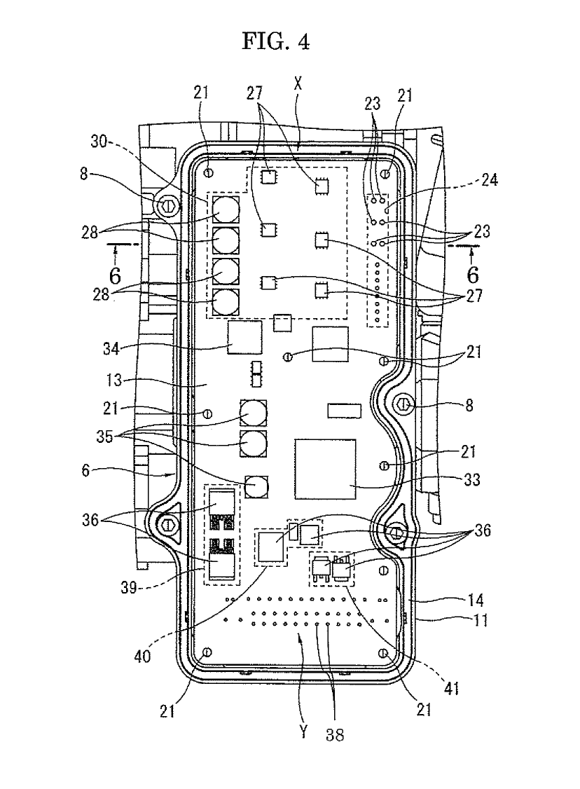

The controller housing 6 is formed as a metal member, for example, a die-casting component made of an aluminum alloy with superior thermal conductivity. As depicted in FIG. 4, a peripheral edge thereof is slightly raised as a flange section 11 from a bottom wall 12 for an entire circumference, and a circuit board 13 is accommodated in a space on the inside of this flange section 11. Note that a seal retaining groove 14, to which an edge of the cover 7 is fitted with an undepicted seal material, is recessed in the flange section 11.

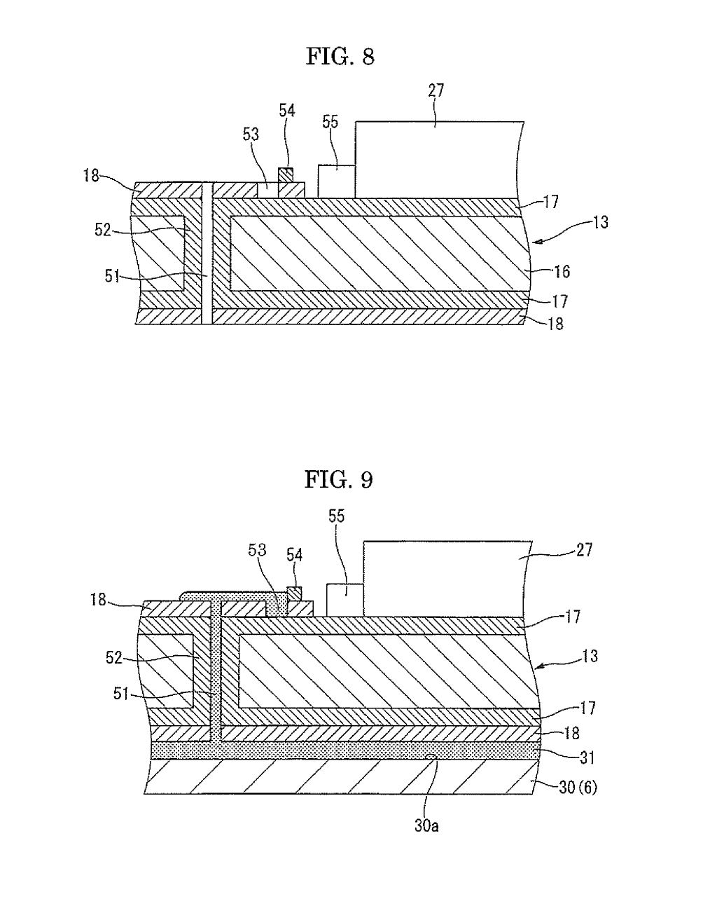

As schematically depicted in FIG. 8 and FIG. 9, in the circuit board 13, a conductive metal layer 17 and an insulation layer (a resist) 18 are stacked on front and back surfaces of a base material 16, for example, a resin base material 16 that is made of a glass epoxy resin or the like, and a number of electronic components are mounted on both of the front and back surfaces thereof as will be described below. Note that a metal substrate can also be used as the circuit board 13 in the invention.

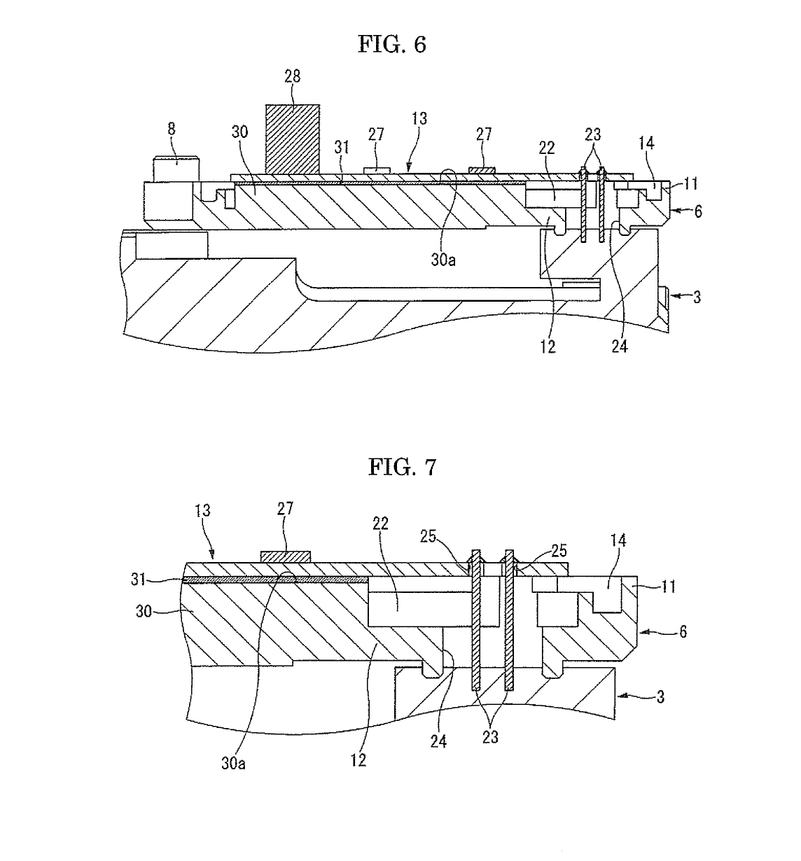

The circuit board 13 is fixed to the controller housing 6 by plural screws 21 that are arranged at plural points on an peripheral edge and at one central point (see FIG. 4), and a slight gap 22 (see FIG. 6) is secured between the circuit board 13 and the bottom wall 12 of the controller housing 6. Accordingly, some of the electronic components (not depicted) that are mounted on a back surface (a surface facing the controller housing 6) of the circuit board 13 are accommodated in this gap 22.

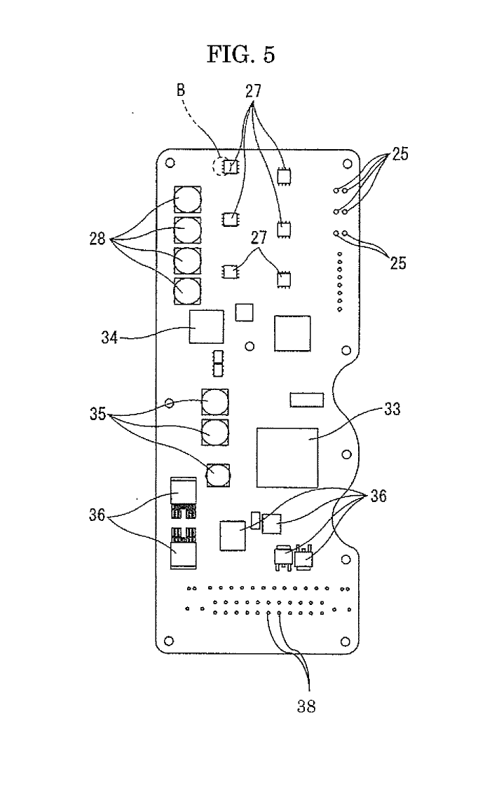

As depicted in FIG. 4, FIG. 6, and FIG. 7, the circuit board 13, which is accommodated in the controller housing 6, and the electric motor (not depicted) in the actuator housing 3 are electrically connected to each other via plural (for example, three and are configured that three motor terminals are forked and soldered at six positions in a board connecting section) of connection terminals 23 that extend from the actuator housing 3. As depicted in FIG. 4, these connection terminals 23 are arranged in a form of “2×3” on one side in an upper portion (an upper right side in FIG. 4) of the controller housing 6, and an elongated rectangular opening 24 is opened and formed in the bottom wall 12 of the controller housing 6 in a manner to correspond to an arrangement area of these three connection terminals 23. Accordingly, as depicted in FIG. 6 and FIG. 7, the three connection terminals 23 that are projected from the actuator housing 3 penetrate the opening 24 of the bottom wall 12 and extend to the circuit board 13. In addition, a tip of each of the connection terminals 23 penetrates a through hole 25 (see FIG. 5 and FIG. 7) that is formed in the circuit board 13, and is soldered to a pattern (not depicted) on the circuit board 13.

Meanwhile, of the electronic components mounted on a front side (a surface facing the cover 7) of the circuit board 13, six semiconductor switching elements (for example, MOS-FETs) 27 and four electrolytic capacitors 28 for an inverter circuit as heat generating components are collectively arranged in an area X that is adjacent to the three connection terminals 23 in the upper portion of the controller housing 6. The semiconductor switching elements 27 are arranged in the form of “2×3” in a central portion in a width direction of the circuit board 13, and the four electrolytic capacitors 28 are vertically aligned in a row on one side that is an opposite side of the connection terminals 23 in the width direction of the circuit board 13.

On aback surface side of the area X, in which these plural heat generating components are collectively arranged, a heat mass 30 is formed in the controller housing 6 by thickening the bottom wall 12 such that a portion thereof becomes one step higher than the rest so as to increase thermal capacity. When being projected as in FIG. 4, this heat mass 30 is formed in a range that includes the six semiconductor switching elements 27 and the four electrolytic capacitors 28. In addition, a top surface 30a of the heat mass 30 is formed as a flat surface, and this top surface 30a and the back surface of the circuit board 13 are joined via a thermal conductive adhesive 31 (see FIG. 6 and FIG. 7). The thermal conductive adhesive 31 is an adhesive that contains an appropriate filler to increase thermal conductivity, and an adhesive of a thermal hardening type can be used, for example. Note that the top surface 30a of the heat mass 30 corresponds to a portion of a bottom surface of the controller housing 6.

In addition to the semiconductor switching elements 27 and the electrolytic capacitors 28, a number of the electronic components that include a CPU 33, a coil 34, an electrolytic capacitor 35, various FETs 36, and the like are mounted on the circuit board 13, and, as described above, some of those are mounted on the back surface of the circuit board 13. Note that, needless to say, no electronic component exists in a portion on the back surface side that comes in contact with the top surface 30a of the heat mass 30.

In addition, an area Y in which a number of through holes 38 are aligned in a lower portion of the circuit board 13 is an area in which connections with terminals of the above-described connector 10 are made. In this embodiment, also in the lower portion of the circuit board 13 that is adjacent to this connector 10, heat masses 39, 40, 41, each of which is formed one step higher, are formed in the bottom wall 12 of the controller housing 6 in a manner to correspond to some of the heat generating components such as the FETs 36. The back surface of the circuit board 13 is joined to a top surface of each of the heat masses 39, 40, 41 via the thermal conductive adhesive 31.

According to the configuration as described above, because the circuit board 13 is fixed to the top surface 30a of the heat mass 30, which is positioned adjacent to the connection terminals 23, via the thermal conductive adhesive 31, vibration of the circuit board 13 caused by vehicle travel vibration or the like is inhibited. In particular, because a portion of the circuit board 13 that is adjacent to the connection terminals 23 is fixed to the controller housing 6, relative displacement or vibration between the tip of the connection terminal 23 that is fixed to the through hole 25 of the circuit board 13 and a base of the connection terminal 23 that is supported by the actuator housing 3 is reduced, and thus a load that is applied to the connection terminal 23 at a time when the connection terminal 23 receives the vehicle travel vibration or the like is reduced. Thus, damage and the like to the connection terminal 23 caused by stress that repeatedly acts thereon are inhibited, and vibration resistance thereof is improved.

In addition, at the same time as local fixation of the circuit board 13 as described above, heat of the semiconductor switching elements 27 and the electrolytic capacitors 28 as the heat generating components is transferred to the heat mass 30 via the thermal conductive adhesive 31, and these semiconductor switching elements 27 and electrolytic capacitors 28 are efficiently cooled.

Furthermore, in the depicted embodiment, also in the lower portion of the circuit board 13, to which the plural terminals of the connector 10 are connected, the circuit board 13 is fixed to the top surfaces of the heat masses 39, 40, 41 via the thermal conductive adhesive 31. Thus, similarly, stress that is caused by the vibration of the circuit board 13 and acts on the terminals of the connector 10 is reduced, and the heat generating components such as the FETs 36 are cooled.

Next, FIG. 8 is an enlarged cross-sectional view that schematically depicts a cross section of the circuit board 13 in a portion B of FIG. 5. As depicted in this drawing, plural through holes 51 are formed around the semiconductor switching elements 27 and the electrolytic capacitors 28 as the heat generating components in order to increase heat dissipation. The depicted through hole 51 is formed as a so-called thermal via formed with a metal layer 52 on an inner circumferential surface such that the conductive metal layers 17 on the front and back surfaces of the resin base material 16 are connected to each other. Note that the through hole 51 may be a simple through hole that is not equipped with the metal layer 52 in an inner circumference.

Regarding the through hole 51 that is arranged adjacent to the heat generating component, for example, a solder connecting section 55 of a terminal of the semiconductor switching element 27, a recessed groove 53 that separates the through hole 51 and the solder connecting section 55 from each other is formed between the through hole 51 and the solder connecting section 55 by cutting the insulation layer 18 in a line shape or a belt shape. Note that the deeper recessed groove 53 may be formed through two layers of the insulation layer 18 and the conductive metal layer 17 if necessary and if formation thereof on the circuit pattern is possible.

Furthermore, a dam 54 that is formed with a dummy pattern of a silk pattern is stacked on the insulation layer 18 along an opening edge of the recessed groove 53 on the solder connecting section 55 side. This dam 54 can be formed concurrently with printing of a silk pattern of other required letters and numbers (for example, a model number and the like) on the front surface of the circuit board 13.

FIG. 9 depicts a state where the circuit board 13 that includes such through holes 51 is assembled to the controller housing 6 via the thermal conductive adhesive 31. The thermal conductive adhesive 31 that is arranged between the heat mass 30 and the circuit board 13 as described above has fluidity at a stage of being unhardened. The thermal conductive adhesive 31 enters the through hole 51 around the heat generating component in conjunction with fastening of the screw 21, for example, is brought into a filled state in the through hole 51, and is then hardened.

In the case where the thermal conductive adhesive 31 is filled in the through hole 51 as described above, the thermal conductivity from the conductive metal layer 17 on the front surface side of the circuit board 13 to the conductive metal layer 17 on the back surface side thereof is improved due to a fact that the thermal conductive adhesive 31 is superior to an air layer in terms of the thermal conductivity. This further improves the heat dissipation from the semiconductor switching elements 27 and the electrolytic capacitors 28 as the heat generating components to the heat mass 30.

Here, adhesion and hardening of the thermal conductive adhesive 31, which overflows to the front surface of the circuit board 13 through the through hole 51, to the solder connecting section 55 of the electronic component is not preferred because coefficients of thermal expansion of the thermal conductive adhesive 31 and the solder differ from each other, and stress acts on the solder connecting section 55 over time. To handle this, the recessed groove 53 and the dam 54 are provided between the through hole 51 and the solder connecting section 55 in the configuration of the above embodiment. Thus, even when some amount of the thermal conductive adhesive 31 overflows to the front surface of the circuit board 13 through the through hole 51, as depicted in FIG. 9, the thermal conductive adhesive 31 is stemmed by the recessed groove 53 and the dam 54, and the adhesion thereof to the solder connecting section 55 is inhibited. Note that, as depicted in FIG. 9, attachment of the circuit board 13 to the controller housing 6 that is accompanied by application of the thermal conductive adhesive 31 is performed in such a posture that the circuit board 13 and the controller housing 6 are substantially horizontal.

Thus, generation of the stress caused by the adhesion of the thermal conductive adhesive 31 to the solder connecting section 55 can be inhibited. In addition, the adhesion of the thermal conductive adhesive 31 can be inhibited even when some amount thereof overflows from the through hole 51 as described above. Accordingly, the thermal conductive adhesive 31 can reliably be filled for entire length of the through hole 51, and the thermal conductivity in a thickness direction of the circuit board 13 is improved.

Note that, although the circuit board 13 is adhered and fixed to the top surface 30a of the heat mass 30 that is one step higher as the bottom surface of the controller housing 6, the invention is not limited thereto, and the circuit board 13 only has to be adhered to a portion of the bottom surface of the controller housing 6 via the thermal conductive adhesive 31. In addition, although not all of the heat generating components have to be arranged on the heat mass 30 in the invention, at least all of the six semiconductor switching elements 27, which constitute the inverter circuit, are desirably arranged on the heat mass 30 in an adjacent manner to the connection terminals 23.

In addition, in the embodiment depicted in FIG. 8 and FIG. 9, both of the recessed groove 53 and the dam 54 are used to stem the thermal conductive adhesive 31 that overflows from the through hole 51; however, use of only one of them can suffice.

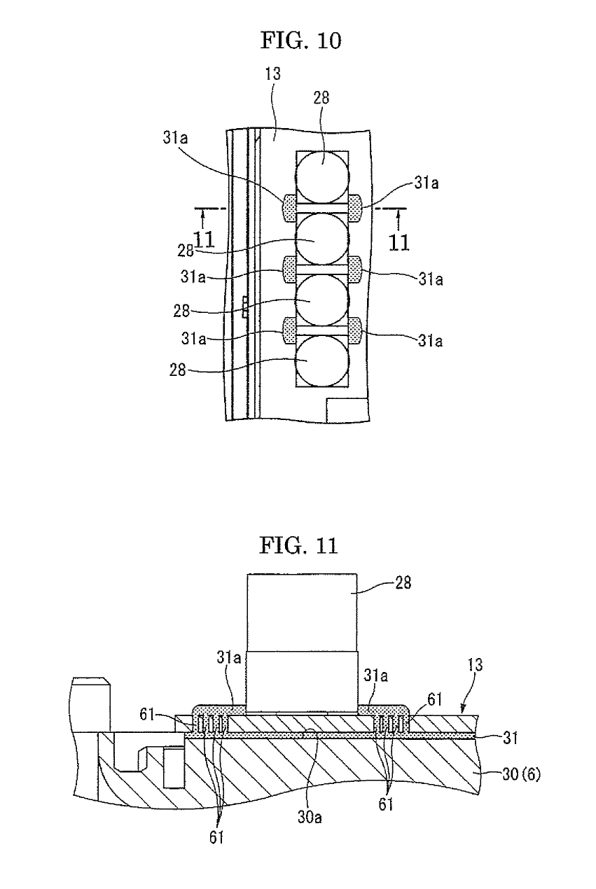

Next, FIG. 10 and FIG. 11 depict a second embodiment in which the thermal conductive adhesive 31 that overflows through the through hole is actively used to fix the heat generating component, for example, the electrolytic capacitor 28. FIG. 10 only depicts a peripheral portion of the four electrolytic capacitors 28 that are arranged above the heat mass 30, and FIG. 11 depicts a cross section along lines 11-11 in FIG. 10. Note that the second embodiment is not particularly different from the above-described embodiment except for a main section, which will be described below.

In this embodiment, one or plural through holes 61 are formed through the circuit board 13 at each of positions between two adjacent electrolytic capacitors 28 on both sides of the four electrolytic capacitors 28 that are aligned in the row. In a depicted example, the four through holes 61 are arranged on each of the sides of the electrolytic capacitor 28. A hole diameter, a position, and the like of each of these through holes 61 are set such that an appropriate amount of the thermal conductive adhesive 31 overflows to the front surface of the circuit board 13.

In the state where the circuit board 13 is attached to the controller housing 6, the unhardened thermal conductive adhesive 31 that is applied between the heat mass 30 and the circuit board 13 enters the through holes 61 in conjunction with fastening of the screw 21, for example, and overflows to the front surface of the circuit board 13. As depicted in FIG. 10 and FIG. 11 by denoting a reference sign 31a, the thermal conductive adhesive 31 that has overflowed as described above spreads around bases of the electrolytic capacitors 28, is hardened, and adheres the electrolytic capacitors 28 to the circuit board 13.

In this way, the electrolytic capacitor 28, height of which is relatively tall and mass of which is large among the various electronic components mounted on the circuit board 13, is firmly supported by the circuit board 13, and supporting strength of the electrolytic capacitor 28 with respect to the vehicle travel vibration or the like is increased.

Although not depicted, adhesion of the thermal conductive adhesive 31 to a solder connecting section of a terminal of the electrolytic capacitor 28 is desirably inhibited by using the recessed groove 53 and the dam 54 as depicted in FIG. 8 and FIG. 9.

The above through hole 61 may be equipped with a metal layer on an inner circumferential surface as a so-called thermal via, or may be a simple through hole that is not equipped with the metal layer in an inner circumference. In either case, the thermal conductive adhesive 31 is hardened in a state of being filled in the through hole 61, and thus, either case contributes to the improvement of the thermal conductivity in the thickness direction of the circuit board 13 as in the above-described embodiment.

Note that, while the description has been made by using the electrolytic capacitor 28 as the example in FIG. 10 and FIG. 11, the thermal conductive adhesive 31 that overflows from the through hole 61 can also be used to fix or reinforce another electronic component.

In addition, the invention is not limited to the controller 5 for the electric brake device of the above embodiment but can be applied to various types of the electronic circuit units.

As it has been described so far, according to the invention, in the electronic circuit unit that includes: the controller housing made of metal; the circuit board that has the heat generating components mounted thereon and is accommodated in this controller housing; and the connection terminals that extend from the outside of the above controller housing and penetrate the controller housing, and the tips of connection terminals are connected to the circuit board, the plural heat generating components are collectively arranged in the area that is adjacent to the connection terminals, and the area of the circuit board is joined to the bottom surface of the controller housing via the thermal conductive adhesive. Accordingly, at the same time as that the heat dissipation of the heat generating components is improved, the circuit board can fixedly be supported by the controller housing at the position near the connection terminals. Thus, the load acting on the connection terminal when the connection terminal receives the vibration from the outside is reduced. In particular, because the plural heat generating components are collectively arranged in the area that is adjacent to the connection terminals, effective fixation support and the improvement in the heat dissipation can be realized by using a minimum amount of the heat conductive adhesive.

In addition, in the preferred embodiment, the portion of the bottom surface of the controller housing that corresponds to the area is formed to be partially thick as the heat mass, and the circuit board is joined to the top surface of this heat mass via the heat conductive adhesive. In this way, cooling of the heat generating components becomes further effective. Because the gap is formed between the bottom surface of the controller housing and the circuit board in the portion other than the heat mass, the electronic components can be mounted on the back surface of the circuit board.

In the one embodiment, the controller housing is attached to the actuator housing, and the connection terminals supported by the actuator housing extend to the circuit board through the opening that is provided in the controller housing. The load acting on such connection terminals is reduced by fixing the circuit board via the thermal conductive adhesive.

In the one embodiment, the through hole that penetrates the circuit board is provided in the area of the circuit board, and the thermal conductive adhesive is filled in the through hole. Thus, the thermal conductivity in the thickness direction of the circuit board is improved.

In the one embodiment, the through hole that penetrates the circuit board at the position adjacent to the heat generating component as the fixation target is provided in the area of the circuit board, and the heat generating component is fixed to the circuit board by the thermal conductive adhesive that overflows from the position between the circuit board and the bottom surface of the controller housing to the circuit board through the through hole. Thus, the supporting strength of the heat generating component is concurrently improved.

In the one embodiment, the through hole that penetrates the circuit board is provided in the area of the circuit board, and the recessed groove that is formed by cutting the metal layer or the insulation layer on the surfaces of the circuit board is formed between the through hole and the solder connecting section of the terminal of the heat generating component that is adjacent to this through hole. Thus, unnecessary adhesion of the thermal conductive adhesive to the solder connecting section can be inhibited.

In the one embodiment, the through hole that penetrates the circuit board is provided in the area of the circuit board, and the dam that is formed with the dummy pattern is stacked between this through hole and the solder connecting section of the terminal of the heat generating component that is adjacent to the through hole. Thus, the unnecessary adhesion of the thermal conductive adhesive to the solder connecting section can be inhibited.

In the one embodiment, as the heat generating components, the plural units of the semiconductor switching elements and the plural units of the electrolytic capacitors that constitute the inverter circuit are arranged in the area. Thus, these heat generating components, each of which has a relatively large heat generation amount, can reliably be cooled.
3: actuator housing
5: controller
6: controller housing
13: circuit board
23: connection terminal
24: opening
27: semiconductor switching element (heat generating component)
28: electrolytic capacitor (heat generating component)
30: heat mass
31: thermal conductive adhesive
51: through hole
53: recessed groove
54: dam
61: through hole

What is claimed is:

1. An electronic circuit unit comprising:
a controller housing made of metal;
a circuit board that has heat generating components mounted thereon and is accommodated in the controller housing; and
a connection terminal that extends from outside of the controller housing and penetrates the controller housing, a tip of the connection terminal being connected to the circuit board,
wherein the heat generating components are arranged in an area of the circuit board, the area being adjacent to the connection terminal, and
wherein the area of the circuit board is joined to a bottom surface of the controller housing via a thermal conductive adhesive.

2. The electronic circuit unit according to claim 1, wherein a portion of the bottom surface of the controller housing that corresponds to the area of the circuit board is formed to be partially thick as a heat mass, and the circuit board is joined to atop surface of the heat mass via the thermal conductive adhesive.

3. The electronic circuit unit according to claim 1, wherein the controller housing is attached to an actuator housing, and the connection terminal supported by the actuator housing extends to the circuit board through an opening provided in the controller housing.

4. The electronic circuit unit according to claim 1, wherein a through hole that penetrates the circuit board is provided in the area of the circuit board, and the thermal conductive adhesive is filled in the through hole.

5. The electronic circuit unit according to claim 1, wherein a through hole that penetrates the circuit board is provided at a position adjacent to the heat generating component as a fixation target in the area of the circuit board, and the heat generating component is fixed to the circuit board by the thermal conductive adhesive that overflows onto the circuit board from a position between the circuit board and the bottom surface of the controller housing through the through hole.

6. The electronic circuit unit according to claim 1, wherein a through hole that penetrates the circuit board is provided in the area of the circuit board, and a recessed groove that is formed by cutting a metal layer or an insulation layer on a surface of the circuit board is formed between the through hole and a solder connecting section of a terminal of the heat generating component that is adjacent to the through hole.

7. The electronic circuit unit according to claim 1, wherein a through hole that penetrates the circuit board is provided in the area of the circuit board, and a dam that is formed with a dummy pattern is formed at a position between the through hole and a solder connecting section of a terminal of the heat generating component that is adjacent to the through hole.

8. The electronic circuit unit according to claim 1, wherein, as the heat generating components, a plurality of semiconductor switching elements and a plurality of electrolytic capacitors that constitute an inverter circuit are arranged in the area of the circuit board.
